(19) United States
(12) Patent Application Publication
(10) Pub. No.: US 2008/0063951 A1
(43) Pub. Date: Mar. 13, 2008

(54) PHOTO-MASK FOR MICRO LENS OF CMOS IMAGE SENSOR

(76) Inventor: Ju-Hyoung Moon, Gyeonggi-do (KR)

Correspondence Address: SHERR & NOURSE, PLLC, 620 HERNDON PARKWAY, SUITE 200, HERNDON, VA, 20170, US

(21) Appl. No.: 11/846,927

(22) Filed: Aug. 29, 2007

(30) Foreign Application Priority Data
Sep. 12, 2006 (KR) 10-2006-0087744

(51) Int. Cl. G03F 1/00

(52) U.S. Cl. 430/5

(57) ABSTRACT

A photo-mask for a micro lens of a CMOS image sensor includes a transparent substrate, a plurality of light-shielding patterns for shielding light, a plurality of semi-shielding patterns which respectively surround the plurality of light-shielding patterns, and a unit mask pattern for the unit micro lens including a complete-shielding region provided over the light-shielding pattern, a semi-shielding region provided over the semi-shielding pattern, and a complete-transmitting region provided over the substrate.

The present application claims priority under 35 U.S.C. 119 to Korean Patent Application No. 10-2006-087744 (filed on Sep. 12, 2006), which is hereby incorporated by reference in its entirety.

### BACKGROUND

An image sensor is a semiconductor device which receives image signals through a photodiode or phototransistor, and converts the image signals to an electric digital image using an analog digital converter (ADC). An image sensor may be classified as a complementary metal oxide semiconductor (CMOS) image sensor (CIS) and a charge coupled device (CCD).

A CMOS image sensor may include a photodiode and a plurality of transistors formed on a semiconductor substrate, at least one metal line layer for electrically connecting respective circuit devices to one another and a plurality of insulating interlayers for electrically insulating the circuit devices and the metal line layers from one another. A color filter array having a plurality of color filters may also be formed on an uppermost insulating interlayer. Each filter contained in the color filter array filter lights having a predetermined wavelength of a corresponding color among three colors (e.g., red, green and blue).

A CIS may further include an array or plurality of micro lenses provided on respective color filters of the color filter array. A planarization layer may be interposed between the color filter array and the plurality of micro lenses to compensate for a step difference between the color filters. The micro lens receives light received through a photodiode or phototransistor is condensed, and converts the condensed light into electric signals. The converted electric signals are then displayed as predetermined images by the transistors.

In comparison to the early production of CCDs, fabrication of a CMOS image sensor may be inferior in terms of quality, simplicity, integration and cost. With the enhanced fabrication technology, the CMOS image sensor is in wide use in small-sized cameras having low power-consumption.

The micro lens serves to maximize the efficiency of the color filter array. The micro lens is created by forming a predetermined pattern using a photoresist having high photosensitivity and enhanced light transmittance. A thermal treatment is applied to the photoresist to obtain a lens-shaped micro lens.

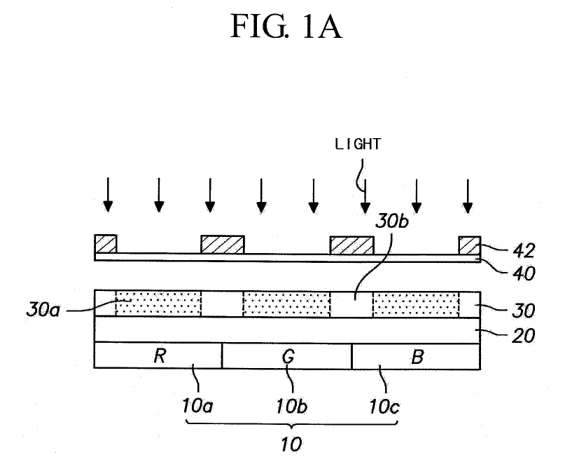

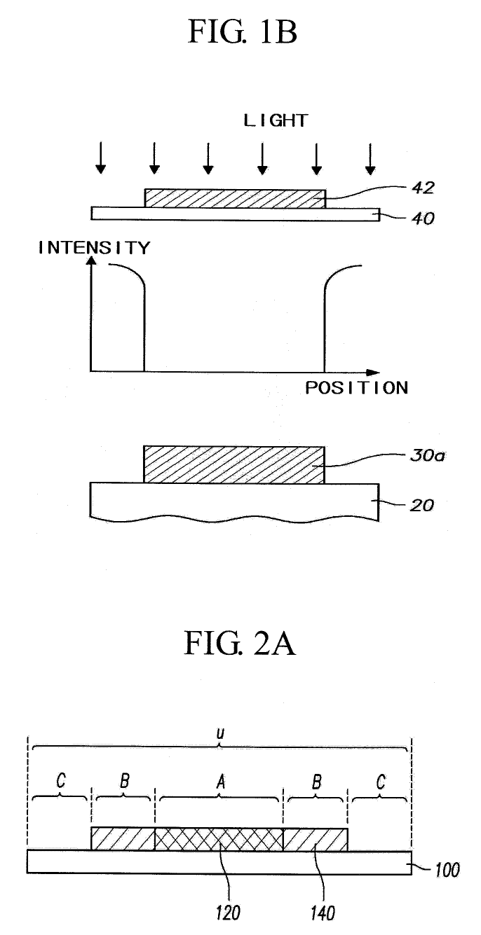

Illustrated in example FIG. 1A is a semiconductor substrate including a photodiode and a plurality of transistors. On the surface of the semiconductor substrate are a plurality of metal line layers for electrically connecting circuit devices, a plurality of insulating interlayers, and color filter array 10 including red 10A, green 10B and blue 10C. The color filter array 10 is positioned on and/or over an uppermost insulating interlayer. Planarization layer 20 is formed on and/or over color filter array 10 in order to compensate for a step difference between color filters 10A, 10B and 10C. Photosensitive photoresist layer 30 is coated on and/or over planarization layer 20 to form a micro lens.

Photoresist layer 30 is then exposed using a photo-mask. Predetermined portion 30b of the unexposed photoresist layer 30 is removed by development while exposed portion 30a of photoresist layer 30 remains on and/or over planarization layer 20, thereby forming a substantially rectangular-shaped photoresist pattern. A reflow and curing process is applied to the photoresist pattern to form a substantially hemispherical micro lens.

Illustrated in example FIG. 1B is a process of forming a photoresist pattern by exposure and development processes. Photoresist layer 30 is exposed using the photo-mask having light-shielding film 42 deposited on and/or over transparent substrate 40. Transparent substrate may be composed of quartz. The exposure level sharply increases at the edge of light-shielding film 42. As unexposed portion 30b is removed by development, photoresist pattern 30a is formed such that its edge has a vertical profile. The separated unit photoresist pattern whose edge profile is vertical is treated with a thermal process to form the micro lens. Accordingly, in order to prevent the bridge due to the overflow in the photoresist pattern, it may be necessary to provide the sufficient margin between photoresist patterns 30b. It may be difficult, however, to obtain the sufficient margin between the patterns after the reflow process due to the thickness of photoresist layer 30. Moreover, fabrication quality is reduced due to the difficulty in establishing a standard for the reflow process of photoresist layer 30.

### SUMMARY

In accordance with embodiments is a photo-mask for forming a micro lens in a CMOS image sensor that does not require that the photoresist undergo a reflow process.

Embodiments include a photo-mask for a micro lens in a CMOS image sensor including a substrate which is transparent to light; a plurality of light-shielding patterns which shields the light; and a plurality of semi-shielding patterns which respectively surround the plurality of light-shielding patterns. A unit mask pattern is repetitively arranged and includes a complete-shielding region provided with the light-shielding pattern, a semi-shielding region provided with the semi-shielding pattern surrounding the light-shielding pattern, and a complete-transmitting region corresponding to the transparent substrate.

### DRAWINGS

Example FIGS. 1A and 1B illustrate a method of fabricating a micro lens.

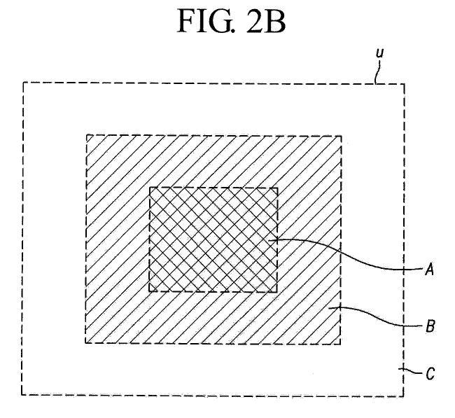

Example FIGS. 2A and 2B illustrate a unit mask pattern in a photo-mask of a micro lens, in accordance with embodiments.

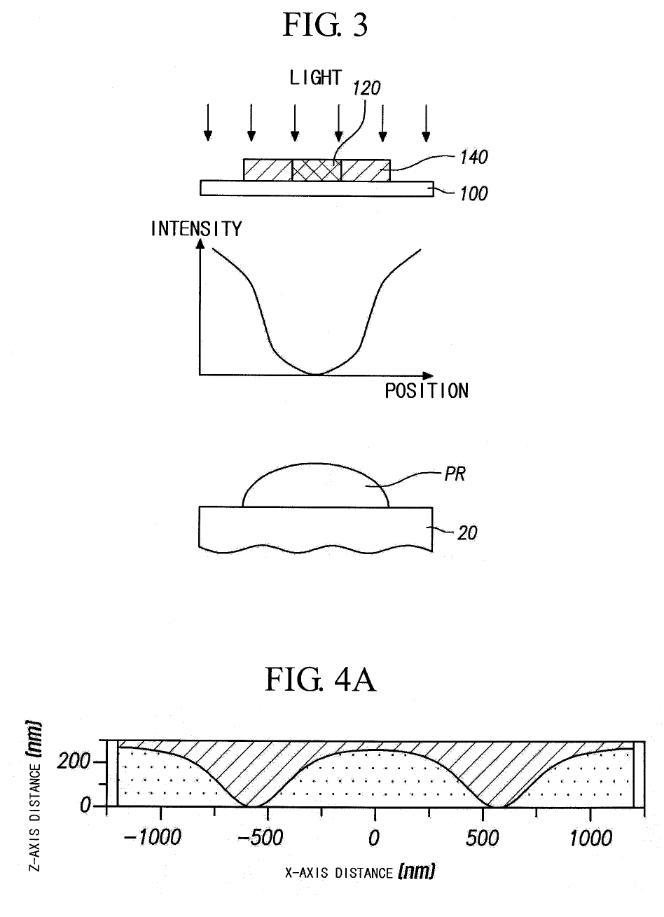

Example FIG. 3 illustrates a process of forming a photoresist pattern using a photo-mask, in accordance with embodiments.

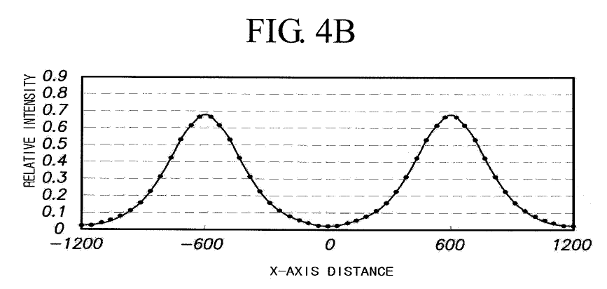

Example FIGS. 4A and 4B illustrate graphs of pre-estimated profiles of a photoresist pattern based computer simulation and light a measurement of light intensity passing through a photo-mask, in accordance with embodiments.

### DESCRIPTION

As illustrated in example FIGS. 2A and 2B, light-shielding pattern 120 is formed on and/or over transparent substrate 100. Transparent substrate 100 may be a transparent quartz substrate. Light-shielding pattern 120 may be composed of a metal material such as chromium (Cr) for shielding light at 100%. Semi-shielding pattern 140 is formed on and/or over substrate 100. Semi-shielding pattern 140 may be formed of a material of a phase-shifting mask or a half-tone mask. Preferably, semi-shielding pattern 140 may be formed of a molybdenum silicide (MoSi) layer. In accordance with embodiments, semi-shielding pattern 140 may be arranged to surround light-shielding pattern 120 so that the light passing through semi-shielding pattern 140 has no phase shift.

The mask pattern shown illustrated in example FIGS. 2A and 2B corresponds to the unit micro lens. The photo-mask may be completed through the repetitive forming of unit mask pattern (U). A region of light-shielding pattern 120 may be used as complete-shielding region (A) which has a light transmittance of 0%. A region of semi-shielding pattern 140 arranged to surround light-shielding pattern 120 may be used as semi-shielding region (B) which partially shields the light. Other exposed regions of substrate 100 not covered by light-shielding pattern 120 or semi-shielding pattern 140 may be used as a complete-transmitting region (C). The light transmittance in semi-shielding region (B) may be between approximately 0% and 100%. The light transmittance in semi-shielding region (B) may be approximately 10%.

As illustrated in example FIG. 3, a schematic illustration of a process of forming a photoresist pattern using a photo-mask in accordance with embodiments so as to enable formation of a photoresist layer as a lens without requiring an additional reflow process.

As illustrated in example FIG. 4A, a pre-estimated profile of a photoresist pattern based on a computer simulation when forming a photoresist pattern by the photo-mask in accordance with embodiments. Particularly, example FIG. 4 illustrates the intensity of light passing through the photo-mask when a photoresist layer is exposed by the photo-mask in accordance with embodiments.

As illustrated in examples FIGS. 4A and 4B, use of the photo-mask in accordance with embodiments, the curve illustrating the intensity of light passing through the photo-mask is formed as a gentle lens shape. Consequently, if the image intensity of the lens shape is shifted to the photoresist layer, the photoresist pattern formed by development is also formed in the lens shape. As a result, it is unnecessary to carry out an additional reflow process after forming the unit photoresist pattern having a rectangular cross-section. A more simplistic method of forming a micro lens is provided in accordance with embodiments.

Semi-shielding pattern 140 may be formed in a multi-layered structure where the light transmittance is gradually decreased from complete-transmitting region (C) to complete-shielding region (A). In this case, the lens shape in intensity curve of the light passing through the photo-mask becomes gentler. If the area occupied by semi-shielding region (B) in unit mask pattern (U) is one-half of the unit micro lens, the intensity curve of light passing through the photo-mask is formed as a hemisphere.

The photo-mask in accordance with embodiments yields several advantages. For instance, use of the photo-mask eliminates the need for a reflow process for the photoresist pattern. The elimination of this step enhances the overall fabrication process for a micro lens. It may also be possible to precisely control gaps between respective micro lens, thereby preventing cross-talk caused by the gap between the micro lens.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a substrate which is transparent to light;
a plurality of light-shielding patterns for shielding light formed over the substrate;
a plurality of semi-shielding patterns surrounding the plurality of light-shielding patterns formed over the substrate; and
a plurality of mask patterns formed over the substrate, wherein the plurality of mask patterns include a complete-shielding region provided over the light-shielding patterns, a semi-shielding region provided over the semi-shielding patterns, and a complete-transmitting region provided over the substrate.

2. The apparatus of claim 1, wherein the plurality of light-shielding patterns comprise metal layers.

3. The apparatus of claim 2, wherein the metal layers comprise chromium.

4. The apparatus of claim 1, wherein the plurality of light-shielding patterns have a light transmittance of 0% at the complete-shielding region.

5. The apparatus of claim 1, wherein the plurality of semi-shielding patterns are formed of at least one of materials for a phase-shifting mask and a half-tone mask.

6. The apparatus of claim 5, wherein the plurality of semi-shielding patterns comprises molybdenum silicide.

7. The apparatus of claim 1, wherein the plurality of semi-shielding patterns have a light transmittance of between approximately 0% and 100% at the semi-shielding region.

8. The apparatus of claim 1, wherein the plurality of semi-shielding patterns have a light transmittance of 10%.

9. The apparatus of claim 7, wherein the plurality of semi-shielding patterns are formed in a multi-layered structure where light transmittance is gradually decreased from the complete-transmitting region to the complete-shielding region.

10. The apparatus of claim 1, wherein an area occupied by the semi-shielding region in the unit mask pattern corresponds to approximately one-half the size of a unit micro lens.

11. A method comprising:
forming a plurality of light-shielding patterns over a transparent substrate;
forming over the transparent substrate a plurality of semi-shielding patterns; and
forming a plurality of mask patterns over the transparent substrate,
wherein the plurality of mask patterns include a complete-shielding region provided over the light-shielding patterns, a semi-shielding region provided over the semi-shielding patterns, and a complete-transmitting region provided over the substrate.

12. The method of claim 11, wherein the plurality of light-shielding patterns comprise a metal material.

13. The method of claim 12, wherein the metal material comprises chromium.

14. The method of claim 11, wherein the plurality of light-shielding patterns shield light at 100%.

15. The method of claim 11, wherein the plurality of semi-shielding patterns comprise a material of a phase-shifting mask or a half-tone mask

16. The method of claim 11, wherein the plurality of semi-shielding patterns comprise molybdenum silicide.

17. The method of claim 11, wherein the plurality of semi-shielding patterns are arranged to surround the plurality of light-shielding pattern so that light passing through the plurality of semi-shielding patterns has no phase shift.

18. The method of claim 11, wherein the plurality of semi-shielding patterns are arranged in a multi-layered structure where light transmittance is gradually decreased from the complete-transmitting region to the complete-shielding region.

19. The method of claim 11, wherein the complete-shielding region has a light transmittance of 0%.

20. The method of claim 11, wherein the semi-shielding region has a light transmittance of between approximately 0% and 100%.
